(19) United States
(12) Patent Application Publication
(10) Pub. No.: US 2014/0118900 A1
(43) Pub. Date: May 1, 2014

(54) ELECTRONIC DEVICE WITH COMPACT FITTING OF DISK DRIVE

(71) Applicants: HONG FU JIN PRECISION INDUSTRY (ShenZhen) CO., LTD., (US); HON HAI PRECISION INDUSTRY CO., LTD., New Taipei (TW)

(72) Inventors: CHIH-WEI CHIEN, New Taipei (TW); WEN-YI HSIAO, New Taipei (TW); BIEN-CHI YANG, New Taipei (TW); ZHAN-YAN WEN, Shenzhen (CN); MING-GE HOU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/859,050

(22) Filed: Apr. 9, 2013

(30) Foreign Application Priority Data
Oct. 31, 2012 (CN) 2012104266344

(51) Int. Cl. H05K 5/02

(52) U.S. Cl. CPC H05K 5/02
USPC 361/679.01

(57) ABSTRACT

An electronic device includes a main body having a top wall, a bottom wall and a front sidewall, and a hard disk drive received in the main body adjacent to the front sidewall. The hard disk drive includes a first end adjacent to the front sidewall and a second end parallel to and opposite to the first end. The hard disk drive is mounted at a slant to the top wall, at an angle of α, and the distance between the first end and the top wall is less than the distance between the second end and the top wall, to slant up the hard disk drive, allowing the thickness of a front portion of the main body adjacent to the front sidewall to be thinner and cosmetically sleeker.

### BACKGROUND

1. Technical Field

The present disclosure relates to electronic devices, and more particularly to an electronic device having a Hard Disk Drive (HDD).

2. Description of Related Art

Portable electronic devices, such as notebook computer, include a housing and a Hard Disk Drive (HDD) received in the housing. The housing is horizontally mounted in the housing. With the need for thinner portable electronic devices, some electronic devices are designed with the thickness of the peripheral portion being thinner than that of the middle portion. Because of the thinness of the peripheral portions, the space available in the thinner peripheral portions is lessened, and the Hard Disk Drive cannot be horizontally mounted to the housing.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a partial, perspective view of an electronic device in accordance with an embodiment.

FIG. 2 is a disassembled, perspective view of the electronic device of FIG. 1; the electronic device includes a bracket, a circuit board and a connecter.

FIG. 3 is a perspective view of the bracket of FIG. 2.

FIG. 4 is a perspective view showing the connecter mounted to the circuit board of FIG. 2.

FIG. 5 is a cross-sectional view taken along line V-V of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

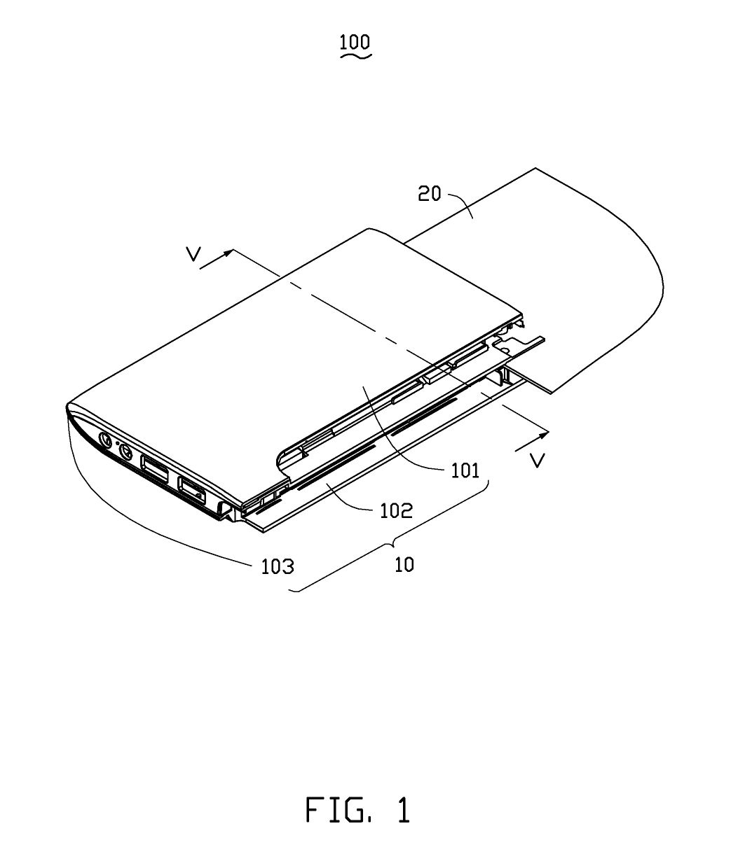

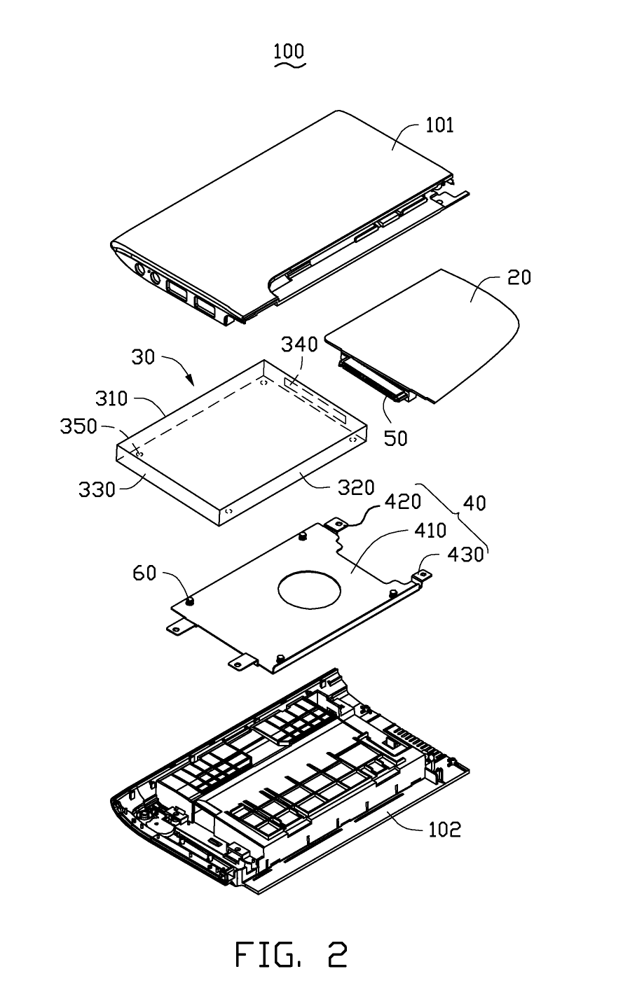

Referring to FIGS. 1 and 2, an electronic device 100 in accordance with an embodiment is shown. The electronic device 100 in the embodiment is a notebook computer with a Hard Disk Drive (HDD). The electronic device 100 includes a main body 10, a display (not shown) rotatably coupled to the main body 10, a circuit board 20 received in the main body 10, a HDD 30 received in the main body 10 and electrically connected to the circuit board 20, and a bracket 40. The bracket 40 is attached to the main body 10 for securing the HDD 30 to the main body 10.

The main body 10 includes a top wall 101, a bottom wall 102 and a front sidewall 103. An end of the bottom wall 102 adjacent to the front sidewall 103 extends slantingly toward the top wall 101, to allow the thickness of the front portion of the main body 10 adjacent to the sidewall 103 to gradually become thinner. When the main body 10 is placed on a supporting surface, such as a table (not shown), the top wall 101 is parallel to the supporting surface. A key board (not shown) is mounted to the top wall 101 and is opposite to the bottom wall 102. A plurality of fixing posts (not shown) protrudes from an inner surface of the top wall 101 facing the bottom wall 102. The fixing posts are used as the foundations of the bracket 40.

The circuit board 20 is received in the main body 10. The circuit board 20 is substantially parallel to the top wall 101.

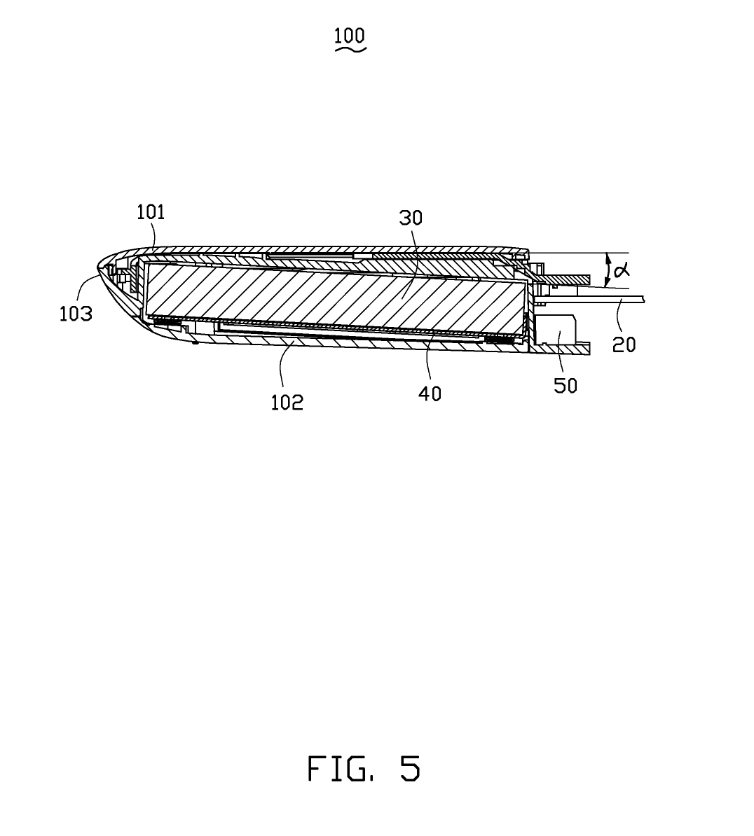

The HDD 30 is substantially rectangular. The HDD 30 is mounted to the main body 10 and is adjacent to the front sidewall 103. The HDD 30 slants relative to the horizontal top wall 101 and keeps an angle α with the top wall 101 (see FIG. 5). The angle α in the embodiment is 5 degrees. The HDD 30 includes a first end 310 adjacent to the front sidewall 103, a second end 320 opposite to the first end 310, and opposite side ends 330. An interface port 340 is arranged on one of the side ends 330 for electrically connecting the HDD 30 to the circuit board 20. The HDD 30 defines four fixing holes 350. The fixing holes 350 are in the four corners of the HDD 30.

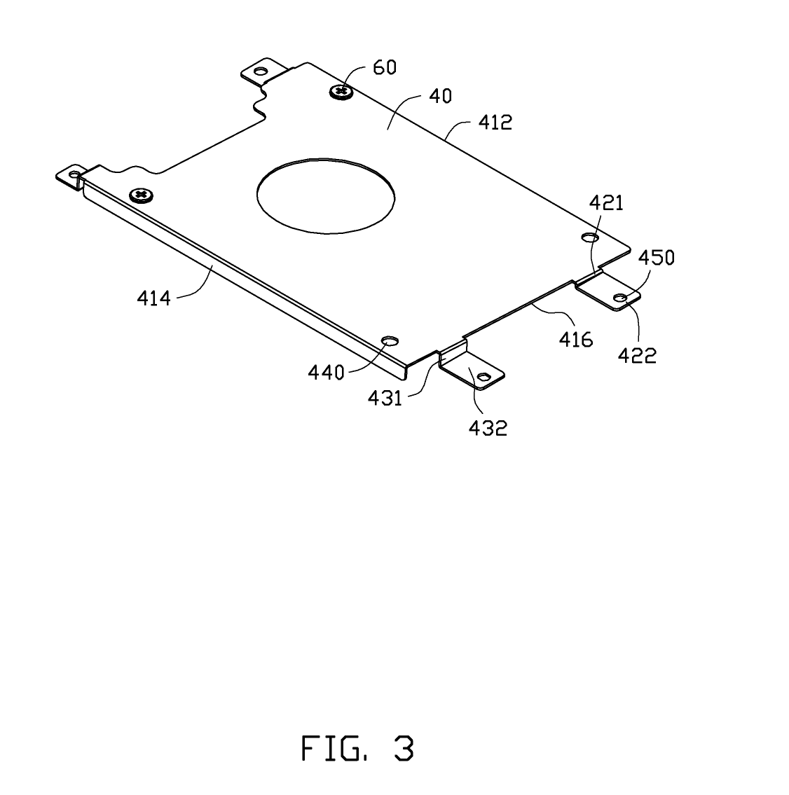

Referring to FIG. 3, the bracket 40 is adapted to fix the HDD 30 to the main body 10, with the distance between the first end 310 and the top wall 101 being less than the distance between the second end 320 and the top wall 101. The bracket 40 includes a base 410, and two first and second fixing members 420, 430.

The base 410 is substantially rectangular. The size of the base 410 is slightly greater than the size of the HDD 30. The base 410 defines four through holes 440. The through holes 440 correspond to the fixing holes 350. The base 410 includes a first rim 412 extending in a direction parallel to the front sidewall 103, a second rim 414 parallel and opposite to the first rim 412, and opposite side rims 416 connected between the first and second rims 412, 414.

The first fixing members 420 are arranged at the side rims 416 and are adjacent to the first rim 412. The first fixing members 420 are aligned parallel to the first rim 412. Each first fixing member 420 includes a first connecting plate 421 and a first fixing arm 422. The first connecting plate 421 protrudes from the side rim 416 and extends toward the top wall 101. A distal end of the first connecting plate 421 away from the base 410 keeps the angle α with the side rim 416. The first fixing arm 422 extends from the distal end of the first connecting plate 421 in a direction away from the base 410. The first fixing arm 422 is parallel to the top wall 101 and keeps the angle α with the base 410.

The second fixing members 420 are arranged at the side rims 416 and are adjacent to the second rim 414. The structure of each second fixing member 420 is similar to that of the first fixing member 410. The difference between the first and second fixing members 420 is that the size of the second connecting plate 431 of each second fixing member 420 is greater than the size of each first connecting plate 421. When viewed from a side of the side rims 416, the distance between the distal ends of the second connecting plates 431 and the base 410 is greater than the distance between the distal ends of the first connecting plates 421. The second fixing arms 434 are aligned and coplanar with the first fixing arms 422. Each of the first and second fixing arms 434 defines a mounting hole 450. The mounting holes 450 receive the fixing posts which protrude from the inner surface of the top wall 101.

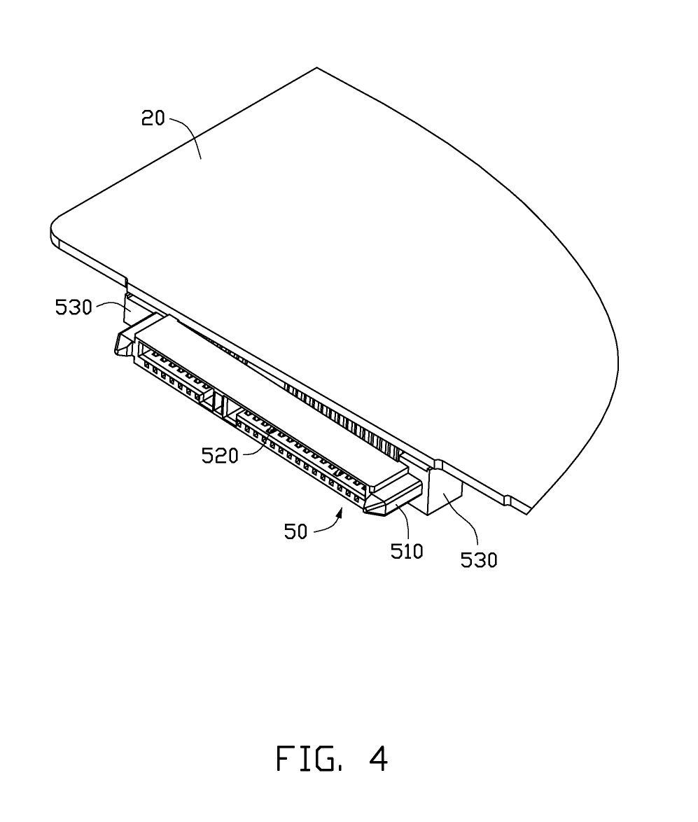

Referring to FIG. 4, the electronic device 100 further includes a connector 50 for electrically connecting the HDD 30 to the circuit board 20. The connector 50 is slantingly secured to the circuit board 20, to engage with the interface port 340 of the HDD 30. The connector 50 includes a housing 510, a plurality of terminals 520 fixed to the housing 510 and electrically connected to the circuit board 20, and two positioning posts 530 for fixing the housing 510. The lengths of the positioning posts 530 are not the same. In the embodiment, ends of the positioning posts 530 away from the circuit board 20 are aligned in a line keeping the angle α with the circuit board 20 and parallel to the base 410. The housing 510 is fixed to ends of the positioning posts 530 away from the circuit board 20, and keeps the angle α with the circuit board 20.

Referring to FIG. 5, in assembly, the connector 50 is mounted on the circuit board 20. The circuit board 20 is secured to the housing 10 and is parallel with the top wall 101. The HDD 30 is fixed to the base 410 by screws 60 extending through the though holes 440 and threading into the fixing holes 350. The connector 50 engages with the interface port 340. Then, the bracket 40 is fixed to the top wall 101 as the mounting holes 450 receive the fixing posts protruding from the inner surface of the top wall 101. Finally, the top wall 101 is engaged with the bottom wall 102.

After assembly, because the first and second fixing arms 422, 432 are coplanar with each other and parallel to the top wall 101, the HDD 30 mounted on the base 410 slants relative to the top wall 101, at the angle of α. Furthermore, because the size of the first connecting plates 421 is less than the size of the second plates 431, after the HDD 30 is secured to the main body 10 by the bracket 40, the first end 310 of the HDD 30 approaches the top wall 101 at a slant, leaving a portion of the space provided by the front portion of the main body 10 (adjacent to the front sidewall 103) unused and available. As a result, the thickness of the front portion of the main body 10 adjacent to the front sidewall 103 can nevertheless be lessened by the designer by taking away the unused portion of the front portion of the main body 10.

Although information as to, and advantages of, the present embodiments have been set forth in the foregoing description, together with details of the structures and functions of the present embodiments, the disclosure is illustrative only; and changes may be made in detail, especially in the matters of shape, size, and arrangement of parts within the principles of the present embodiments to the full extent indicated by the broad general meaning of the terms in which the appended claims are expressed.

What is claimed is:

1. An electronic device, comprising:
a main body comprising a top wall, a bottom wall and a front sidewall; and
a Hard Disk Drive received in the main body and adjacent to the front sidewall, the Hard Disk Drive comprising a first end adjacent to the front sidewall and a second end parallel and opposite to the first end;
wherein the Hard Disk Drive is slantingly mounted on and keeps an angle α with the top wall, and the distance between the first end and the top wall is less than the distance between the second end and the top wall, to allow an end of the bottom wall adjacent to the front sidewall to slantingly extend toward the top wall, to lessen the thickness of a front portion of the main body adjacent to the front sidewall.

2. The electronic device of claim 1, further comprising a bracket, wherein the bracket slantingly fixes the Hard Disk Drive to the top wall.

3. The electronic device of claim 2, wherein the bracket comprises a base for holding the Hard Disk Drive, and two first and second fixing members for fixing the bracket to the top wall.

4. The electronic device of claim 3, wherein the base comprises a first rim parallel and adjacent to the front sidewall, a second rim opposite to the first rim, and opposite side rims; the first fixing members are arranged at opposite side rims and are adjacent to the first rim, the second fixing members are arranged at opposite side rims and are adjacent to the second rim.

5. The electronic device of claim 4, wherein each first fixing member comprises a first connecting plate extending from the side rim and toward the top wall, each second fixing member comprises a second connecting plate extending from the side rim and toward the top wall, the size of the first connecting plate is less than the size of the second connecting plate.

6. The electronic device of claim 5, wherein each first fixing member further comprises a first fixing arm, the first fixing arm extends from a distal end of the first connecting plate away from the side rim; each second fixing member further comprises a second fixing arm, the second fixing arm extends from a distal end of the second connecting plate away from the side rim.

7. The electronic device of claim 5, wherein each first and second fixing arm defines a mounting hole for fixing the first and second fixing members to the top wall.

8. The electronic device of claim 1, further comprising a circuit board received in the main body and a connector for electrically connecting the Hard Disk Drive to the circuit board.

9. The electronic device of claim 8, wherein the Hard Disk Drive has an interface port, the connector is slantingly mounted on the circuit board and keeps an angle α with the top wall to engage with the interface port.

10. The electronic device of claim 9, wherein the connector comprises a housing, a plurality of terminals fixed to the housing and electrically connected to the circuit board, and two positioning posts for fixing the housing to the circuit board.

11. The electronic device of claim 10, wherein the length of the positioning posts are different, ends of the positioning posts away from the circuit board are aligned to keep an angle α with the top wall.
